(19) United States
(12) Patent Application Publication
(10) Pub. No.: US 2008/0248640 A1
(43) Pub. Date: Oct. 9, 2008

(54) Method for reducing polysilicon gate defects in semiconductor devices

(75) Inventors: Yiming Gu, Richardson, TX (US); Gary Zhang, Plano, TX (US); Craig Hall, Allen, TX (US)

Correspondence Address: TEXAS INSTRUMENTS INCORPORATED, P O BOX 655474, M/S 3999, DALLAS, TX, 75265, US

(73) Assignee: Texas Instruments Inc.

(21) Appl. No.: 11/732,969

(22) Filed: Apr. 5, 2007

(51) Int. Cl. H01L 21/3205

(52) U.S. Cl. 438/585

(57) ABSTRACT

Semiconductor devices and fabrication methods are provided, in which gate defects associated with photoresist stress after plasma trim/etch are substantially reduced. The method comprises forming a gate dielectric layer above a semiconductor body substrate; coating the gate dielectric layer with a photoresist coating; exposing and developing the photoresist coating; performing a resist annealing; and trimming and etching the photoresist coating.

### FIELD OF INVENTION

The present invention relates generally to semiconductor devices and more particularly to methods for making the same.

### BACKGROUND OF THE INVENTION

Field effect transistors (FETs) are widely used in the electronics industry for switching, amplification, filtering, and other tasks related to both analog and digital electrical signals. Most common among these are polysilicon-oxide-semiconductor field-effect transistors (FETs), wherein a gate contact or electrode is energized to create an electric field in a channel region of a semiconductor body, by which electrons are allowed to travel through the channel between a source region and a drain region of the semiconductor body. The source and drain regions are typically formed by adding dopants to targeted regions on either side of the channel. A gate dielectric or gate oxide is formed over the channel, and a gate electrode or gate contact is formed over the gate dielectric. The gate electrode is often made from polysilicon rather than metal in manufacturing. The gate dielectric and gate electrode layers are then patterned to form a gate structure overlying the channel region of the substrate.

Continuing trends in semiconductor product manufacturing include reduction in electrical device feature sizes (scaling), as well as improvements in device performance in terms of device switching speed and power consumption. Transistor performance may be improved by reducing the distance between the source and the drain regions under the gate electrode of the device, known as the gate or channel length, and by reducing the thickness of the layer of gate oxide that is formed over the semiconductor surface. Critical dimension (CD) or gate length continues to be reduced in successive technology generations.

FETs are typically made by first defining active areas in a substrate 10 by forming isolation regions 15 consisting of insulating material like silicon dioxide as shown in FIG. 1a. Isolation regions can be generated by local oxidation of silicon (LOCOS) or by a shallow trench isolation (STI) technique. A thin gate oxide layer 20 is grown over the substrate between the isolation regions 15 and then a gate electrode material 25 such as polysilicon is deposited on the gate oxide. Next, a hardmask 30 is deposited on gate electrode layer 25. Optionally, an antireflective coating (ARC) 35 is coated on the hardmask 30, or an inorganic film, such as silicon oxynitride, will be deposited on the hardmask in order to improve process latitude during a subsequent photoresist patterning step. A photoresist is spin coated to provide a photoresist layer 40 and is patterned using conventional methods to form a line having a width L1 in FIG. 1a. Photoresist 40 then serves as an etch mask for etching the pattern through ARC 35.

Frequently, L1 is not narrow enough to meet the requirements for a fast transistor speed. Therefore, fabrication methods usually include a resist trimming step in which a plasma etch is used to laterally shrink dimension L1 to a smaller size L2 shown in FIG. 1b. The height H1 of photoresist layer 40 decreases to a thickness H2 in the etched photoresist film. Linewidth L2 is transferred into hardmask 30 to give an etched hardmask layer shown FIG. 1c.

Referring to FIG. 1d, photoresist 40 and ARC 35 are stripped and linewidth L2 in hardmask 30 is etch transferred through polysilicon 25 and oxide layer 20. Additional processing (not shown) to fabricate the MOSFET can include forming spacers on the sides of etched polysilicon layer 25, forming source/drain regions and source/drain extensions to define a channel and forming silicide contact regions.

Problems exist which are associated with the lithography process used to form photoresist lines. One of the shortcomings in state of the art lithography processes is that they are incapable of printing the desired feature size with enough process window. Many semiconductor manufacturers have overcome this problem using a trimming process which laterally shrinks the photoresist line with an etch step.

However, there are also problems associated with trimming photoresist which can degrade gate pattern fidelity and decrease device performance, as well as reliability. Such gate problems include, among others, line notching, line top erosion, and poor step-height induced from STI (shallow trench isolation) CMP (chemical mechanical polishing) coverage, which are strongly correlated to an accumulation of resist stress after the trimming process.

Accordingly, there is a need for improved CMOS transistor gate designs and fabrication techniques by which the benefits of scaling can be achieved while avoiding or reducing the poly gate defects associated with accumulating resist stress induced by the resist trim and etch process.

### SUMMARY OF THE INVENTION

In one embodiment, the invention is directed to a method of reducing polysilicon gate defects in a semiconductor device, the method comprising forming a gate dielectric layer above a semiconductor body substrate; coating the gate dielectric layer with a resist coating; exposing and developing the resist coating; performing a resist annealing; and trimming and etching the photoresist coating.

In another embodiment, the invention is directed to a semiconductor device having reduced gate defects associated with accumulating resist stress, wherein the gate defects are reduced by annealing a resist coating applied to a substrate body of the semiconductor device.

### BRIEF DESCRIPTION OF THE DRAWINGS

FIGS. 1a-1d depict a prior art process for trimming a photoresist line to provide a small CD in a MOSFET device.

FIG. 2 is a simplified flow diagram illustrating a method of fabricating a gate structure of a field effect transistor in accordance with the present invention.

FIG. 3 is a SEM photograph of a portion of a patterned semiconductor device.

FIG. 4 and FIG. 5 are SEM photographs of a portion of FIG. 2 following with and without resist annealing in accordance with an embodiment of the invention.

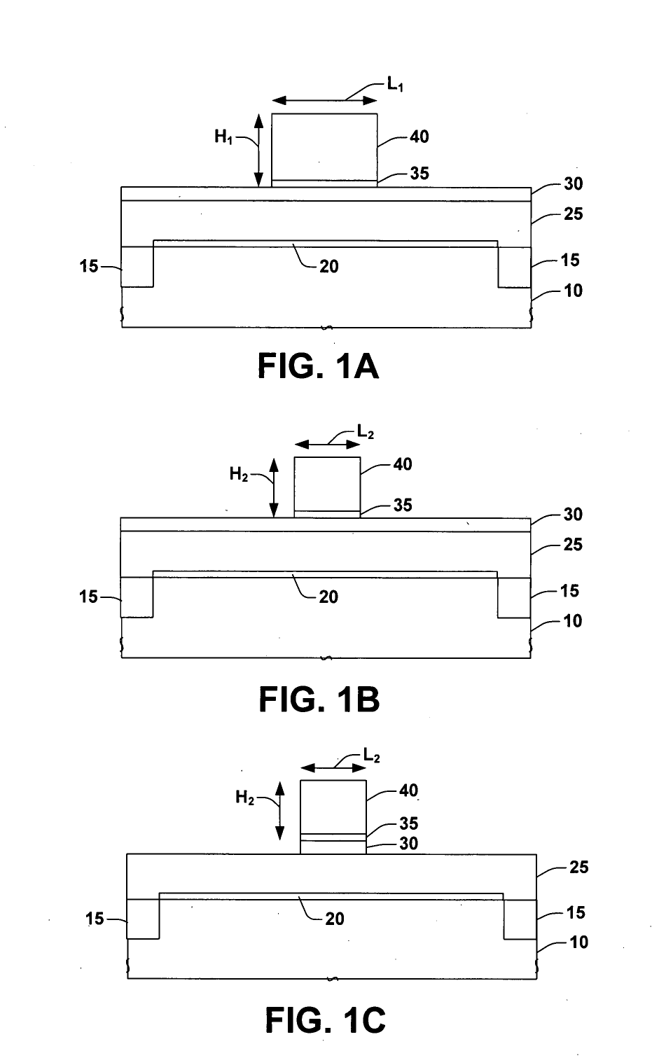

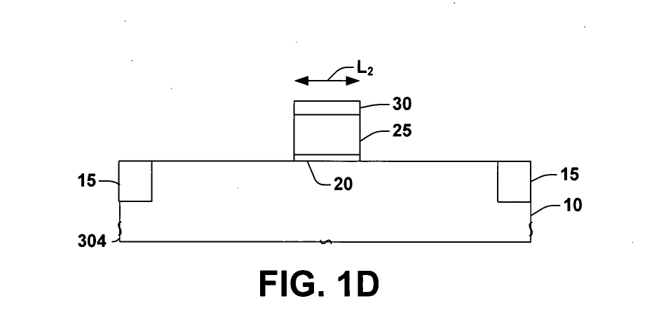

### DETAILED DESCRIPTION OF THE INVENTION

One or more implementations of the present invention will now be described with reference to the attached drawings, wherein like reference numerals are used to refer to like elements throughout, and wherein the illustrated structures are not necessarily drawn to scale. The invention relates to polysilicon gate CMOS devices and fabrication methods. The invention may be employed to enhance the device yield and the device reliability, by mitigating or eliminating the defects associated with resist stress from resist trimming and etching.

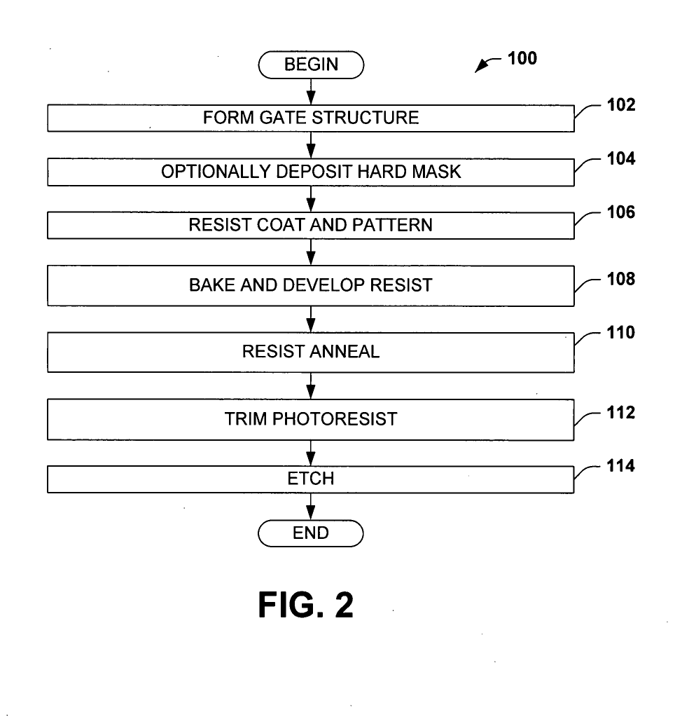

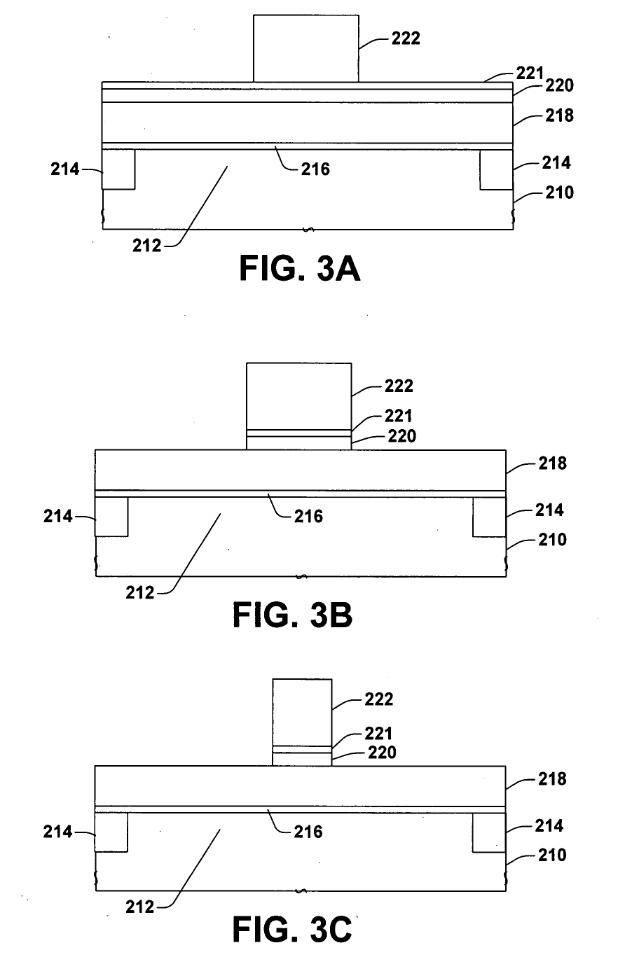

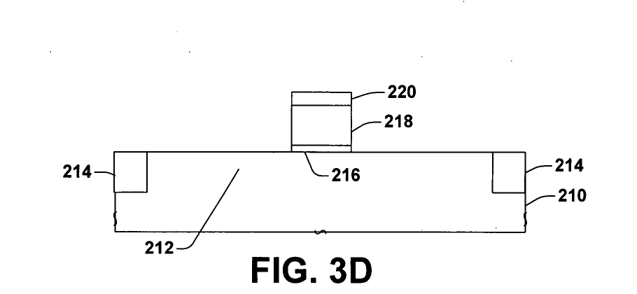

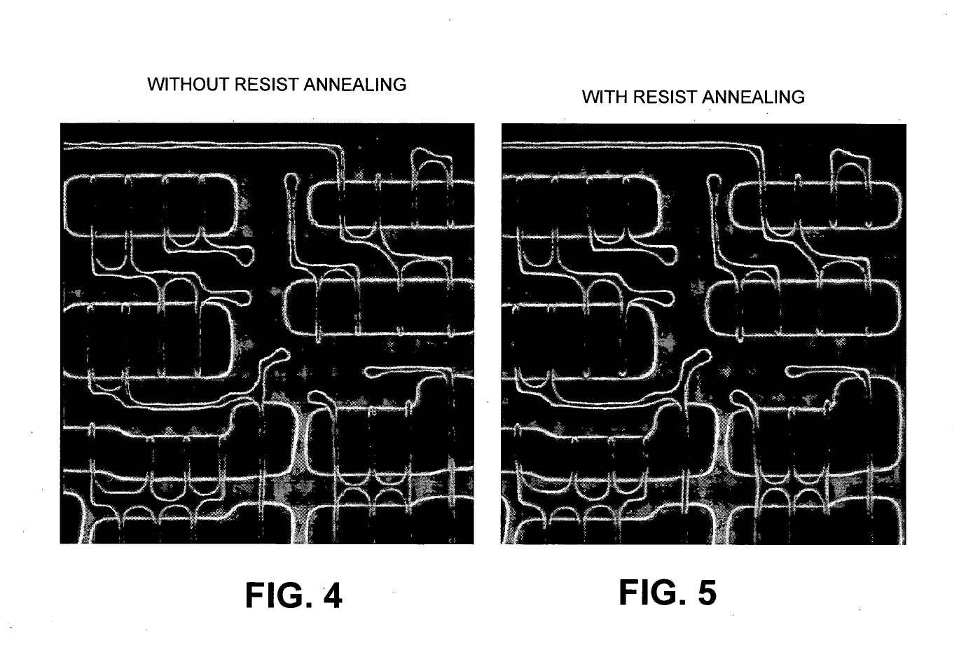

Referring initially to FIG. 2, together with FIGS. 3a-3d, an exemplary method 200 is illustrated in FIG. 2 for fabricating a gate electrode in accordance with the present invention. The sequence 100 comprises process steps that are performed upon a gate electrode film-stack during fabrication of a field effect transistor. While the exemplary method 100 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Further, the methods according to the present invention may be implemented in association with the formation and/or processing of structures illustrated and described herein as well as in association with other structures and devices not illustrated.

The methods and devices of the invention may be implemented using any type of semiconductor substrate body, including but not limited to bulk semiconductor wafers (e.g., silicon), epitaxial layers formed over a bulk semiconductor, SOI wafers, etc. The substrate 210 has an active area 212 located between two isolation regions 214. Isolation regions may be formed by shallow trench isolation (STI). The STI regions 214 are filled with an insulating material such as silicon dioxide or a low k dielectric material. A gate dielectric layer 216 is formed 102 on substrate 210 using any suitable materials, material thicknesses, and processing steps, including thermal oxidation or deposition or combinations thereof to form a gate dielectric above the semiconductor substrate. For instance, the gate dielectric layer 216 may be formed by chemical vapor deposition (CVD) and may comprise silicon oxide, silicon nitride, or silicon carbide. When gate dielectric layer 216 is silicon oxide, it may also be formed by placing substrate 210 in a thermal oxidation furnace with a dry oxygen ambient at approximately 600° C. to 800° C. Other methods such as RTO (rapid thermal oxidation) may also be used to grow an oxide layer. A polysilicon layer 218 is deposited on dielectric layer 216 by a CVD method. Polysilicon layer 218 may be doped or undoped.

The process sequence 100 continues with the optional step of depositing 104 a hardmask 220 over polysilicon layer 218. The hardmask 220 may comprise silicon rich nitride covered by silicon oxynitride (SiON), silicon dioxide (Si)₂), or other material. The optional hardmask 120 functions to protect the polisilicon from etch and minimize reflection of light during patterning steps. In one embodiment, an optional ARC 221 can be applied directly over the polysilicon layer 218 without hardmask 220. In another embodiment, ARC 221 can be deposited over hardmask 220 to improve the process latitude further within a subsequent photoresist patterning process.

Following deposition 104 of the optional hardmask 220 and ARC 221 layers, a photoresist layer 222 is formed and deposited 106. The photoresist layer 222 may be formed using any conventional technique. The photoresist layer 222 is patterned by forming a patterned mask (e.g., photoresist mask) on the underlying layer (polysilicon layer 218 or optional hardmask layer 220) beneath the mask and then etching the layer using the patterned mask as an etch mask. Those skilled in the art understand the process for forming and patterning the photoresist layer 222, and thus no further detail is warranted.

A post-exposure bake 108 of the photoresist 222 is then performed. Bake temperatures will generally be around 130° C. and are dependent on the type of resist. Bake time will vary, and will generally be from about 30 seconds to about 90 seconds. Exposed portions of the photoresist 222 are removed by a developer, while the remaining photoresist 222 retains a pattern.

In the implementation of the invention, a resist anneal or thermal bake process 110 is then performed following post-exposure bake and development 108. The temperature range at which the anneal 110 is performed will be dependent upon the type of photoresist 222 applied. Within this temperature range, the critical dimensions are constant and not sensitive to temperature. Generally, it has been found that the temperature range T₁ to T₂ will be near but lower than a reflow temperature of the photoresist 222. Reflow temperature is defined as the temperature at which the resist gate length will be increased. The temperature range from T₁ to T₂ will be dependent on different resist designs, but within a range of 5° C.-7° C. below the reflow temperature. Further operational settings of the annealing process 110 (e.g., time, etc.) may be selected to depend on post-etch results. Generally, the annealing time will be varied from about 30 seconds to about 90 seconds.

Not wishing to be bound by theory, it is thought that a reduction in gate defects may be obtained as the resist trim time is reduced due to post-pattern critical dimension shrinkage after resist annealing and the stiffness of the resist pattern is enhanced by the removal of more solvent from the resist after applying the resist anneal 110 according to the invention. Following the anneal process 110, it has been observed that the resist pattern has a smaller critical dimension, better LER and LWR, higher resist stiffness and a more uniform resist profile. Such improvements have not been observed for traditional hard bake processes, which are performed at temperatures less than 150° C. or less than the glass transition temperature of the photoresist coating after development.

The device then continues through a conventional dry trimming and etch process as is know in the art.

Although the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a, manner similar to the term “comprising”.

What is claimed is:

1. A method of reducing polysilicon gate defects in a semiconductor device, the method comprising:
forming a gate dielectric layer above a semiconductor body substrate;
coating the gate dielectric layer with a photoresist coating;
exposing and developing the photoresist coating;
performing a resist annealing; and
trimming and etching the photoresist coating.

2. The method of claim 1, wherein said annealing is performed within a temperature range near but lower than a reflow temperature of the photoresist coating.

3. The method of claim 2, wherein the reflow temperature is defined by the type of photoresist coating.

4. The method of claim 2, wherein said resist annealing is performed within a temperature range between temperature T₁ and temperature T₂.

5. The method of claim 4, wherein the temperature T₁ and temperature T₂ varies within a range of 5-7° C. below the reflow temperature.

6. The method of claim 1, wherein the post-exposure bake comprises baking at a temperature of about 130° C. for a time of about 30 seconds to about 90 seconds.

7. The method of claim 2, wherein the annealing occurs for a time of from about 30 seconds to about 90 seconds.

8. The method of claim 1, further comprising pre-baking the photoresist coating prior to exposure and post-baking the photoresist coating following exposure.

9. The method of claim 8, wherein pre-baking is at a temperature of from about 110° C. to about 120° C. and post-baking is at a temperature of from about 110° C. to about 140° C.

10. A semiconductor device made by the method of claim 1.

11. A semiconductor device having reduced gate defects associated with accumulating resist stress, wherein the gate defects are reduced by annealing a photoresist coating applied to a substrate body of the semiconductor device.

12. The semiconductor device of claim 11, wherein said gate defects include one or more of line edge roughness, line width roughness, top erosion and notching.

13. The semiconductor device of claim 11, wherein annealing of the photoresist coating is performed at a temperature near but lower than a reflow temperature of the resist coating.

14. The semiconductor device of claim 13, wherein the reflow temperature is a temperature at which gate length begins increasing.

15. The semiconductor device of claim 14, wherein the annealing temperature between temperature T₁ and temperature T₂ varies within a range of 5-7° C.

16. The semiconductor device of claim 11, wherein annealing occurs for a time of from about 30 seconds to about 90 seconds.
